(19) United States
(12) Patent Application Publication
(10) Pub. No.: US 2026/0068195 A1
(43) Pub. Date: Mar. 5, 2026

(54) METAL-INSULATOR-METAL CAPACITOR STRUCTURE AND FABRICATION METHOD THEREOF

(71) Applicant: UNITED MICROELECTRONICS CORP., Hsin-Chu City (TW)

(72) Inventors: Chih-Wei Kuo, Tainan City (TW); Wen-Wen Zhang, Changhua County (TW); Bo-Han Huang, Chiayi County (TW); Chung-Yi Chiu, Tainan City (TW)

(73) Assignee: UNITED MICROELECTRONICS CORP., Hsin-Chu City (TW)

(21) Appl. No.: 18/898,621

(22) Filed: Sep. 26, 2024

(30) Foreign Application Priority Data
Aug. 30, 2024 (TW) 113132770

(51) Int. Cl. H01L 23/522

(52) U.S. Cl. CPC H10D 1/696

(57) ABSTRACT

A metal-insulator-metal (MIM) capacitor structure including a substrate; a first electrode layer disposed on the substrate; a first capacitor dielectric layer disposed on the first electrode layer; a second electrode layer disposed on the first capacitor dielectric layer; a sidewall protection layer disposed on a sidewall of the second electrode layer; and a dielectric cap layer conformally covering the first electrode layer, the sidewall protection layer, and the second electrode layer.

### BACKGROUND OF THE INVENTION

### 1. Field of the Invention

The present invention relates to the field of semiconductor technology, and in particular to a metal-insulator-metal (MIM) capacitor structure and a manufacturing method thereof.

### 2. Description of the Prior Art

To suppress power line noise in high-speed processor chips, metal-insulator-metal (MIM) capacitors are often used as decoupling capacitors (DCC) in the copper back-end process. Due to its high compatibility with current semiconductor processes, SiN thin film is a candidate material for the dielectric layer of MIM capacitors.

However, the fabrication process of existing MIM capacitors faces challenges when etching the top electrode, as a higher over-etching rate can damage the underlying TiN layer, while a lower over-etching rate can result in TiN residues on the SiN film.

### SUMMARY OF THE INVENTION

It is one object of the present invention to provide an improved metal-insulator-metal (MIM) capacitor structure and a manufacturing method thereof to solve the deficiencies or shortcomings of the existing technology.

One aspect of the invention provides a metal-insulator-metal (MIM) capacitor structure including a substrate; a first electrode layer disposed on the substrate; a first capacitor dielectric layer disposed on the first electrode layer; a second electrode layer disposed on the first capacitor dielectric layer; a sidewall protection layer disposed on a sidewall of the second electrode layer; and a dielectric cap layer conformally covering the first electrode layer, the sidewall protection layer, and the second electrode layer.

According to some embodiments, the first electrode layer comprises a first TiN layer and a TaN layer on the first TiN layer, and wherein the first capacitor dielectric layer is in direct contact with the TaN layer.

According to some embodiments, the first electrode layer further comprises a first Al layer under the first TiN layer and a second TiN layer under the first Al layer.

According to some embodiments, the first capacitor dielectric layer comprises a silicon nitride layer.

According to some embodiments, the silicon nitride layer has a thickness of 50-300 angstroms.

According to some embodiments, the top electrode layer comprises a third TiN layer on the first capacitor dielectric layer, a second Al layer on the third TiN layer, and a fourth TiN layer on the second Al layer.

According to some embodiments, the sidewall protection layer comprises a first TiON layer on a sidewall of the third TiN layer, an aluminum oxide layer on a sidewall of the second Al layer, and a second TiON layer on a sidewall of the fourth TiN layer.

According to some embodiments, the MIM capacitor structure further comprises a second capacitor dielectric layer disposed on the second electrode layer; and a third electrode layer disposed on the second capacitor dielectric layer.

According to some embodiments, the second capacitor dielectric layer is in direct contact with the sidewall protection layer.

According to some embodiments, the second capacitor dielectric layer comprises an aluminum oxide layer sandwiched by two zirconium oxide layers, and wherein the third electrode layer comprises a fifth TiN layer.

Another aspect of the invention provides a method for forming a metal-insulator-metal (MIM) capacitor structure. A substrate is provided. A first electrode layer is formed on the substrate. A first capacitor dielectric layer is formed on the first electrode layer. A second electrode layer is formed on the first capacitor dielectric layer. A sidewall protection layer is formed on a sidewall of the second electrode layer. A dielectric cap layer is formed on the first electrode layer, the sidewall protection layer, and the second electrode layer.

According to some embodiments, the first electrode layer comprises a first TiN layer and a TaN layer on the first TiN layer, and wherein the first capacitor dielectric layer is in direct contact with the TaN layer.

According to some embodiments, the first electrode layer further comprises a first Al layer under the first TiN layer and a second TiN layer under the first Al layer.

According to some embodiments, the first capacitor dielectric layer comprises a silicon nitride layer.

According to some embodiments, the silicon nitride layer has a thickness of 50-300 angstroms.

According to some embodiments, the top electrode layer comprises a third TiN layer on the first capacitor dielectric layer, a second Al layer on the third TiN layer, and a fourth TiN layer on the second Al layer.

According to some embodiments, the sidewall protection layer comprises a first TiON layer on a sidewall of the third TiN layer, an aluminum oxide layer on a sidewall of the second Al layer, and a second TiON layer on a sidewall of the fourth TiN layer.

According to some embodiments, the method further comprises the steps of forming a second capacitor dielectric layer on the second electrode layer; and forming a third electrode layer on the second capacitor dielectric layer.

According to some embodiments, the second capacitor dielectric layer is in direct contact with the sidewall protection layer.

According to some embodiments, the second capacitor dielectric layer comprises an aluminum oxide layer sandwiched by two zirconium oxide layers, and wherein the third electrode layer comprises a fifth TiN layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 5 are schematic diagrams illustrating a method for forming a metal-insulator-metal (MIM) capacitor structure 10 according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

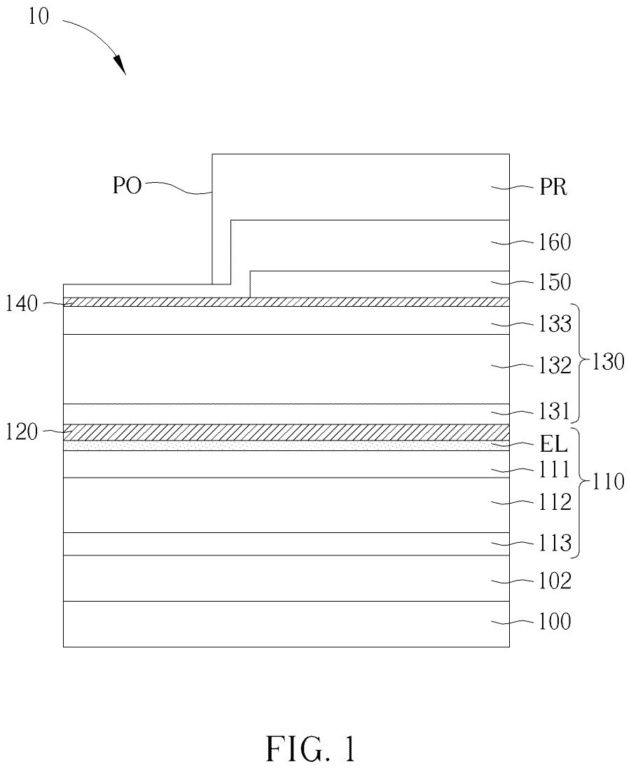

Please refer to FIGS. 1 to 5, which are schematic diagrams illustrating a method for forming a metal-insulator-metal (MIM) capacitor structure 10 according to an embodiment of the present invention. As shown in FIG. 1, a substrate 100 is first provided. For example, the substrate 100 may be a silicon substrate. For the sake of simplicity, transistor elements, insulating structures, and interconnect layers on the substrate 100 are not shown. According to an embodiment of the present invention, an inter-metal dielectric layer 102, such as a silicon oxide layer, may be formed on the substrate 100. Subsequently, a first electrode layer 110 is formed on the inter-metal dielectric layer 102 using a chemical vapor deposition (CVD) process or a physical vapor deposition (PVD) process. According to an embodiment of the present invention, the first electrode layer 110 may be a multi-layer structure including, for example, a first TiN layer 111, a first Al layer 112, and a second TiN layer 113. According to an embodiment of the present invention, the first electrode layer 110 further includes a TaN layer EL disposed on the first TiN layer 111.

According to an embodiment of the present invention, a first capacitor dielectric layer 120 is then formed on the first electrode layer 110. According to an embodiment of the present invention, the first capacitor dielectric layer 120 is in direct contact with the TaN layer EL of the first electrode layer 110. According to an embodiment of the present invention, for example, the first capacitor dielectric layer 110 includes a silicon nitride layer, with a thickness of, for example, 50-300 angstroms.

According to an embodiment of the present invention, a second electrode layer 130 is then formed on the first capacitor dielectric layer 120 using a chemical vapor deposition (CVD) process or a physical vapor deposition (PVD) process. According to an embodiment of the present invention, for example, the second electrode layer 130 may include a third TiN layer 131 located on the first capacitor dielectric layer 120, a second Al layer 132 located on the third TiN layer 131, and a fourth TiN layer 133 located on the second Al layer 132.

According to an embodiment of the present invention, a second capacitor dielectric layer 140 can optionally be formed on the second electrode layer 130, and then a third electrode layer 150 can be formed on the second capacitor dielectric layer 140. According to an embodiment of the present invention, the second capacitor dielectric layer 140 may include an aluminum oxide layer sandwiched between two zirconium oxide layers, i.e., a well-known ZAZ dielectric structure, but is not limited thereto. According to an embodiment of the present invention, the third electrode layer 150 may include a fifth TiN layer. The third electrode layer 150 is a patterned electrode layer. According to an embodiment of the present invention, an insulating layer 160, such as a silicon nitride layer, may be deposited to cover the third electrode layer 150 and the second capacitor dielectric layer 140.

Next, a photoresist pattern PR is formed on the insulating layer 160, defining the pattern of the second electrode layer 130. The photoresist pattern PR includes an opening PO, exposing a portion of the insulating layer 160. In some embodiments, the second capacitor dielectric layer 140 and the third electrode layer 150 may be omitted, and the insulating layer 160 directly covers the second electrode layer 130.

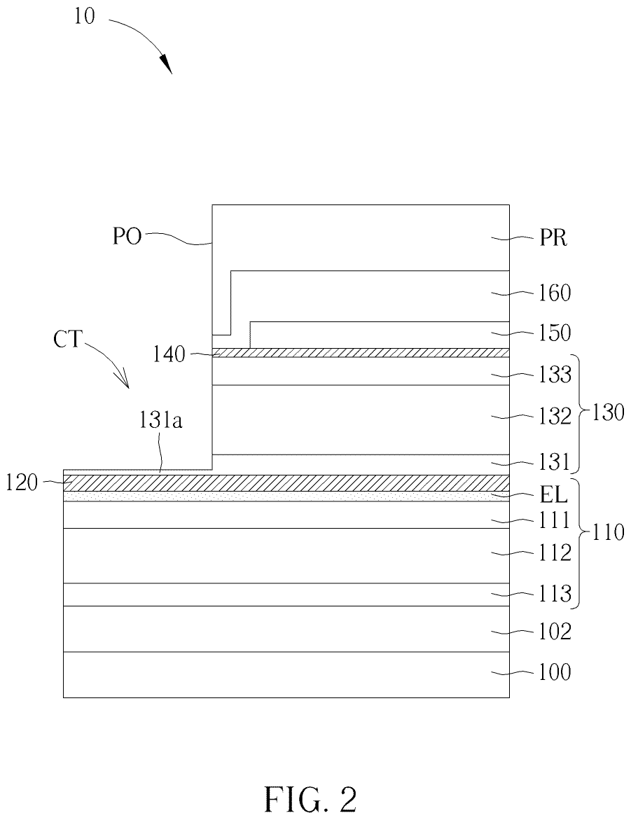

As shown in FIG. 2, an anisotropic dry etching process is performed to etch through the insulating layer 160, the second capacitor dielectric layer 140, the fourth TiN layer 133 and the second Al layer 132 of the second electrode layer 130, and partially etch the third TiN layer 131 of the second electrode layer 130 via the opening PO of the photoresist pattern PR, forming an opening CT. At this point, the first capacitor dielectric layer 120 in the opening CT is still covered by a thin TiN layer 131a. The remaining photoresist pattern PR is then removed.

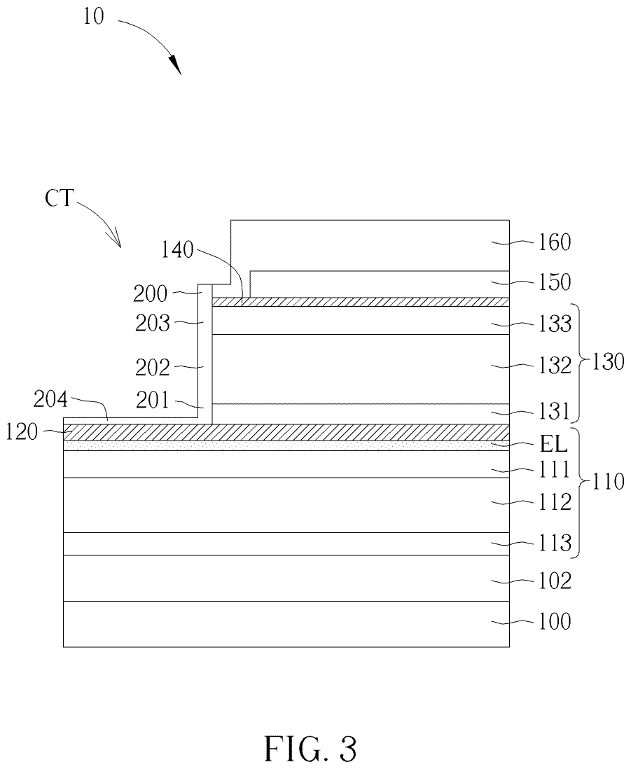

As shown in FIG. 3, an oxidation process is then performed to form a protective layer 200 on the sidewall of the second electrode layer 130 and the third TiN layer 131 exposed in the opening CT. According to an embodiment of the present invention, for example, the protective layer 200 may comprise an oxide layer or an oxynitride layer. According to an embodiment of the present invention, for example, the protective layer 200 may include a first titanium oxynitride (TiON) layer 201 on the sidewall of the third TiN layer 131, an aluminum oxide layer 202 on the sidewall of the second Al layer 132, a second titanium oxynitride layer 203 on the sidewall of the fourth TiN layer 133, and a third titanium oxynitride layer 204 formed by oxidation of the thin TiN layer 131a. According to an embodiment of the present invention, the thin TiN layer 131a may be completely converted into a titanium oxynitride layer.

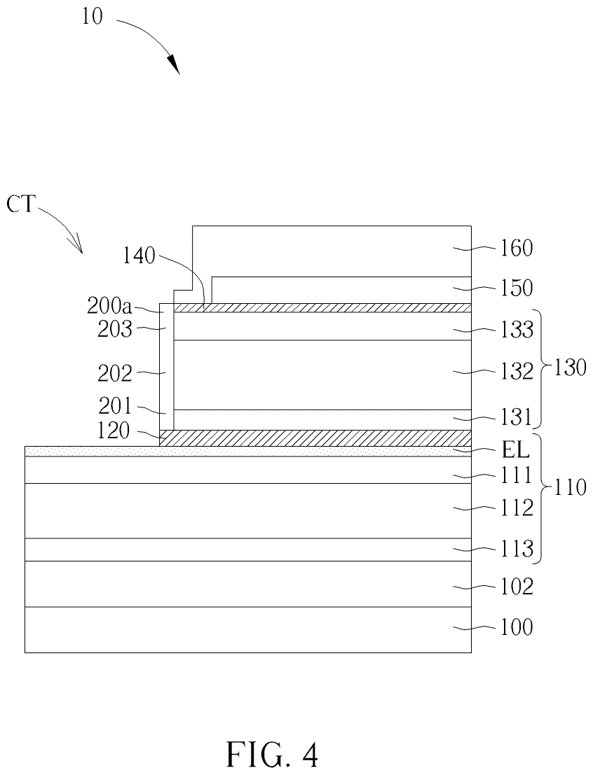

As shown in FIG. 4, an anisotropic dry etching process is performed to etch away the protective layer 200 located on the first capacitor dielectric layer 120 and a portion of the first capacitor dielectric layer 120, exposing a portion of the TaN layer EL, thereby forming a sidewall protection layer 200a on the sidewall of the second electrode layer 130. According to an embodiment of the present invention, the second capacitor dielectric layer 140 may be in direct contact with the sidewall protection layer 200a.

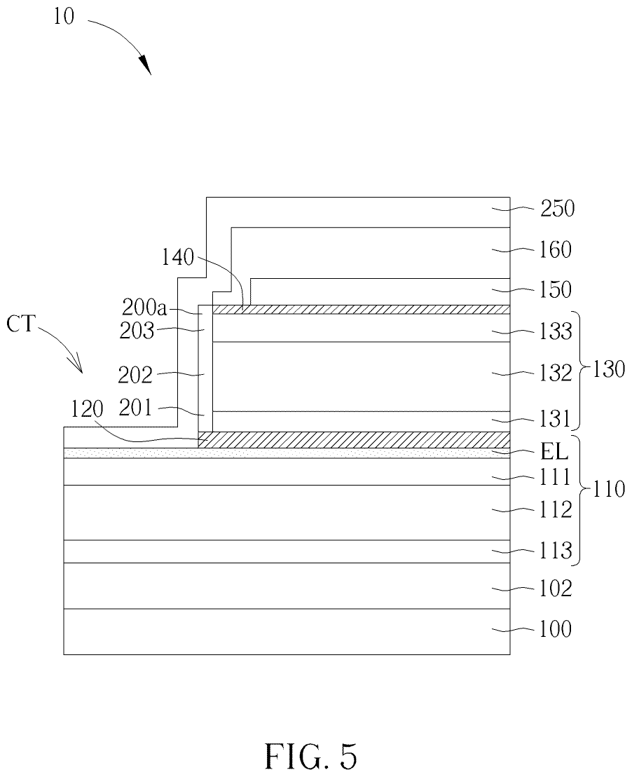

As shown in FIG. 5, a chemical vapor deposition (CVD) process is then performed to conformally deposit a dielectric cap layer 250 on the first electrode layer 110, the sidewall protection layer 200a, and the second electrode layer 150. According to an embodiment of the present invention, the dielectric cap layer 250 may be a silicon nitride layer, but is not limited thereto.

Structurally, as shown in FIG. 5, the metal-insulator-metal (MIM) capacitor structure 10 includes a substrate 100; a first electrode layer 110 disposed on the substrate 100; a first capacitor dielectric layer 120 disposed on the first electrode layer 110; a second electrode layer 130 disposed on the first capacitor dielectric layer 120; a sidewall protection layer 200a disposed on the sidewall of the second electrode layer 130; and a dielectric cap layer 250 conformally covering the first electrode layer 110, the sidewall protection layer 200a, and the second electrode layer 130.

According to an embodiment of the present invention, the first electrode layer 110 includes a first TiN layer 111 and a TaN layer EL disposed on the first TiN layer 111. According to an embodiment of the present invention, the first capacitor dielectric layer 120 is in direct contact with the TaN layer EL. According to an embodiment of the present invention, the first electrode layer 110 further includes a first Al layer 112 disposed below the first TiN layer 111 and a second TiN layer 113 disposed below the first Al layer 112.

According to an embodiment of the present invention, the first capacitor dielectric layer 120 may include a silicon nitride layer. In an embodiment of the present invention, the thickness of the silicon nitride layer is, for example, between 50-300 angstroms.

According to an embodiment of the present invention, the second electrode layer 130 includes a third TiN layer 131 located on the first capacitor dielectric layer 120, a second Al layer 132 located on the third TiN layer 131, and a fourth TiN layer 133 located on the second Al layer 132.

According to an embodiment of the present invention, the sidewall protection layer 200a may include a first TiON layer 201 located on the sidewall of the third TiN layer 131, an aluminum oxide layer 202 located on the sidewall of the second Al layer 132, and a second TiON layer 203 located on the sidewall of the third TiN layer 133.

According to an embodiment of the present invention, the MIM capacitor structure 10 further includes a second capacitor dielectric layer 140 disposed on the second electrode layer 130, and a third electrode layer 150 disposed on the second capacitor dielectric layer 140.

According to an embodiment of the present invention, the second capacitor dielectric layer 140 may be in direct contact with the sidewall protection layer 200a. According to an embodiment of the present invention, the second capacitor dielectric layer 140, for example, includes an aluminum oxide layer sandwiched between two zirconium oxide layers, wherein the third electrode layer 150 comprises a fifth TiN layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A metal-insulator-metal (MIM) capacitor structure, comprising:
a substrate;
a first electrode layer disposed on the substrate;
a first capacitor dielectric layer disposed on the first electrode layer;
a second electrode layer disposed on the first capacitor dielectric layer;
a sidewall protection layer disposed on a sidewall of the second electrode layer; and
a dielectric cap layer conformally covering the first electrode layer, the sidewall protection layer, and the second electrode layer.

2. The MIM capacitor structure according to claim 1, wherein the first electrode layer comprises a first TiN layer and a TaN layer on the first TiN layer, and wherein the first capacitor dielectric layer is in direct contact with the TaN layer.

3. The MIM capacitor structure according to claim 2, wherein the first electrode layer further comprises a first Al layer under the first TiN layer and a second TiN layer under the first Al layer.

4. The MIM capacitor structure according to claim 3, wherein the first capacitor dielectric layer comprises a silicon nitride layer.

5. The MIM capacitor structure according to claim 4, wherein the silicon nitride layer has a thickness of 50-300 angstroms.

6. The MIM capacitor structure according to claim 4, wherein the top electrode layer comprises a third TiN layer on the first capacitor dielectric layer, a second Al layer on the third TiN layer, and a fourth TiN layer on the second Al layer.

7. The MIM capacitor structure according to claim 6, wherein the sidewall protection layer comprises a first TiON layer on a sidewall of the third TiN layer, an aluminum oxide layer on a sidewall of the second Al layer, and a second TiON layer on a sidewall of the fourth TiN layer.

8. The MIM capacitor structure according to claim 7 further comprising:
a second capacitor dielectric layer disposed on the second electrode layer; and
a third electrode layer disposed on the second capacitor dielectric layer.

9. The MIM capacitor structure according to claim 8, wherein the second capacitor dielectric layer is in direct contact with the sidewall protection layer.

10. The MIM capacitor structure according to claim 8, wherein the second capacitor dielectric layer comprises an aluminum oxide layer sandwiched by two zirconium oxide layers, and wherein the third electrode layer comprises a fifth TiN layer.

11. A method for forming a metal-insulator-metal (MIM) capacitor structure, comprising:
providing a substrate;
forming a first electrode layer on the substrate;
forming a first capacitor dielectric layer on the first electrode layer;
forming a second electrode layer on the first capacitor dielectric layer;
forming a sidewall protection layer on a sidewall of the second electrode layer; and
forming a dielectric cap layer on the first electrode layer, the sidewall protection layer, and the second electrode layer.

12. The method according to claim 11, wherein the first electrode layer comprises a first TiN layer and a TaN layer on the first TiN layer, and wherein the first capacitor dielectric layer is in direct contact with the TaN layer.

13. The method according to claim 12, wherein the first electrode layer further comprises a first Al layer under the first TiN layer and a second TiN layer under the first Al layer.

14. The method according to claim 13, wherein the first capacitor dielectric layer comprises a silicon nitride layer.

15. The method according to claim 14, wherein the silicon nitride layer has a thickness of 50-300 angstroms.

16. The method according to claim 14, wherein the top electrode layer comprises a third TiN layer on the first capacitor dielectric layer, a second Al layer on the third TiN layer, and a fourth TiN layer on the second Al layer.

17. The method according to claim 16, wherein the sidewall protection layer comprises a first TiON layer on a sidewall of the third TiN layer, an aluminum oxide layer on a sidewall of the second Al layer, and a second TiON layer on a sidewall of the fourth TiN layer.

18. The method according to claim 17 further comprising:
forming a second capacitor dielectric layer on the second electrode layer; and
forming a third electrode layer on the second capacitor dielectric layer.

19. The method according to claim 18, wherein the second capacitor dielectric layer is in direct contact with the sidewall protection layer.

20. The method according to claim 18, wherein the second capacitor dielectric layer comprises an aluminum oxide layer sandwiched by two zirconium oxide layers, and wherein the third electrode layer comprises a fifth TiN layer.
